(19) United States
(12) Patent Application Publication
(10) Pub. No.: US 2002/0117740 A1
(43) Pub. Date: Aug. 29, 2002

(54) Lead frame for plastic molded type semiconductor package

(75) Inventors: Myungseok Jang, Kyunggi-Do (KR); Inho Kim, Kyunggi-Do (KR); Aekyung Lim, Kyunggi-Do (KR); Soonchang Hong, Kyunggi-Do (KR)

Correspondence Address: LOWE HAUPTMAN GOPSTEIN GILMAN & BERNER, LLP, Suite 310, 1700 Diagonal Road, Alexandria, VA, 22314, US

(73) Assignee: ADVANCED SEMICONDUCTOR ENGINEERING INC.

(21) Appl. No.: 09/794,147

(22) Filed: Feb. 28, 2001

(51) Int. Cl. H01L 23/495; H01L 21/44

(52) U.S. Cl. 257/677; 438/123

(57) ABSTRACT

A lead frame, for a plastic molded type semiconductor package, comprises a plurality of leads and a die pad surrounded by the leads wherein a surface of the die pad is adapted for mounting a semiconductor chip. Areas on the leads adapted for wire bonding are plated with at least one noble metal. The lead frame is characterized in that the at least one noble metal is plated on the surface of die pad in a manner that a central region as well as at least a portion of the brim region of the die pad are kept un-plated. In the lead frame of the present invention, bare copper surface on the un-plated region of the die pad provides improved adhesion to molding compound thereby enhancing the reliability of the finished package. The lead frame may be further provided with a rectangular groove, cavities, mesh-type notches, or through-holes formed in the un-plated brim region of the die pad thereby providing mechanical interlock mechanism to strengthen the bonding between the die pad and the package body.

### BACKGROUND OF THE INVENTION

1. Field of the Invention

This invention generally relates to a lead frame for a plastic molded type semiconductor package, and more particularly to a lead frame having a die pad providing improved adhesion to molding compound.

2. Description of the Related Art

FIG. 1 depicts a plastic molded type semiconductor package comprising a lead frame for supporting a semiconductor chip 100. The lead frame includes a plurality of leads having outer lead portions 106 and inner lead portions 107. The chip 100 is attached onto a die pad 111 using a die attach adhesive such as silver paste 114. The die pad 111 is connected to the lead frame by supporting bars 112 (see FIG. 2). The outer lead portions 106 are used for electrical coupling to an outside circuit. The chip 100 has bonding pads electrically interconnected to the inner lead portions 107 of the lead frame through bonding wires 115, and predetermined areas of the die pad 111 through bonding wires 116. The chip 100, the die pad 111, the inner lead portions 107 of the lead frame and bonding wires 115, 116 are encapsulated in a plastic package body 117 made of molding compound such as epoxy.

In the conventional package described above, the leads are connected to the receiving or transmitting pads on the chip, while the predetermined areas of the die pad are connected to the ground potential. Thus, in these packages, the ground potential can be supplied in any desired positions on the die pad, so it is possible to shorten the ground potential feed lines to suppress power source noises and attain speed-up of the operation of the chip.

The lead frame is typically made of a copper-base alloy, and shaped by pressing or etching. Usually, the lead frame is partially plated with at least one noble metal, for wire bonding purpose. Specifically, as shown in FIG. 2, inner lead portions 107 as well as die pad boundary area 111a of the lead frame are plated with Ag, Ni/Pd, or Ni/Pd/Au such that stable gold wire bonding can be achieved. However, when such kind of conventional package experiences temperature changes, stress occurs at the interface between the package body and the die pad. The stress is generally maximum at the boundary area of the die pad. Therefore, delamination between the package body and the plated area on the die pad boundary area is frequently observed, because of low adhesion therebetween, when this package is subjected to reliability tests such as pressure cooker test (PCT), temperature cycling, or preconditioning including IR Reflow.

Therefore, there is a need in the semiconductor packaging industry for a lead frame having a die pad providing improved adhesion to molding compound.

### SUMMARY OF THE INVENTION

It is a primary object of the present invention to provide a lead frame having a die pad for mounting a semiconductor chip wherein at least a portion of the brim region of the die pad is kept un-plated thereby providing improved adhesion to molding compound.

In order to achieve the object mentioned above, the present invention provide a lead frame, made of a copper alloy, comprising a plurality of leads and a die pad surrounded by the leads wherein a surface of the die pad is adapted for mounting a semiconductor chip. Areas on the leads adapted for wire bonding are plated with at least one noble metal. The lead frame is characterized in that the at least one noble metal is plated on the surface of die pad in a manner that a central region on the surface of the die pad for receiving the semiconductor chip is kept un-plated as well as at least a portion of the brim region of the die pad is kept un-plated. Preferably, the noble metal is selected from the group consisting of silver, gold, and palladium. Since adhesion between molding compound and copper is better than adhesion between molding compound and noble metals described above, bare copper surface on the un-plated region of the die pad provides improved adhesion to molding compound thereby enhancing the reliability of the finished package.

In another preferred embodiment of the present invention, the lead frame is provided with a rectangular groove, cavities, mesh-type notches, or through-holes formed in the un-plated brim region of the die pad thereby providing mechanical interlock mechanism to strengthen the bonding between the die pad and the package body.

Other objects, advantages, and novel features of the invention will become more apparent from the following detailed description when taken in conjunction with the accompanying drawings.

### BRIEF DESCRIPTION OF THE DRAWINGS

FIG. 1 is a cross sectional view of a conventional semiconductor package;

FIG. 2 is a top plan view of a portion of a conventional lead frame;

FIG. 3 is a top plan view of a portion of a lead frame in accordance with a first preferred embodiment of the present invention;

FIG. 4 is a top plan view of a portion of a lead frame in accordance with a second preferred embodiment of the present invention;

FIG. 5 is a top plan view of a portion of a lead frame in accordance with a third preferred embodiment of the present invention;

FIG. 6 is a top plan view of a portion of a lead frame in accordance with a fourth preferred embodiment of the present invention;

FIGS. 7-9 illustrate, in an enlarged cross-sectional view, the lead frame in accordance with the fourth preferred embodiment of the present invention;

FIG. 10 is a top plan view of a portion of a lead frame in accordance with a fifth preferred embodiment of the present invention;

FIGS. 11-12 illustrate, in an enlarged cross-sectional view, a plurality of cavities (FIG. 11) or through-holes (FIG. 12) formed in the brim region of the die pad; and

FIG. 13 is a top plan view of a portion of a lead frame in accordance with a sixth preferred embodiment of the present invention.

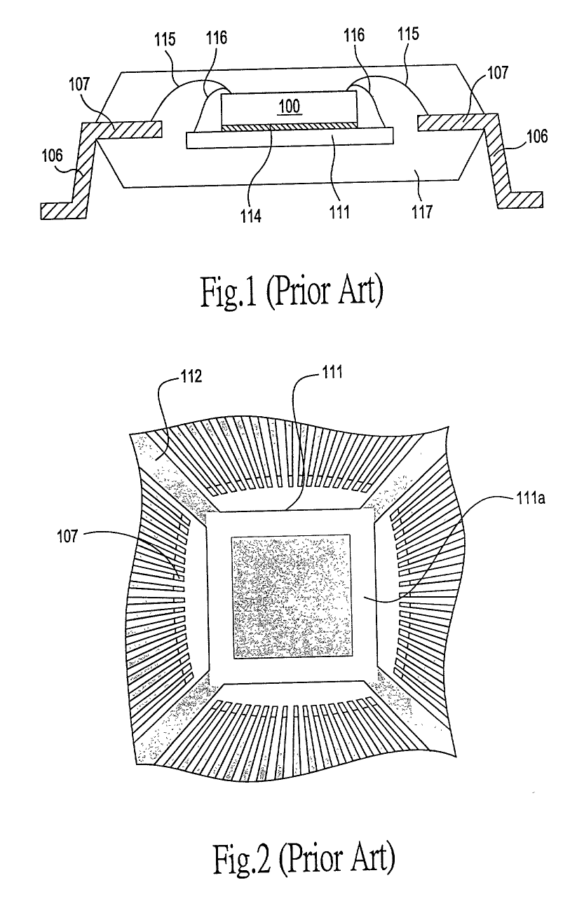

### DETAILED DESCRIPTION OF THE PREFERRED EMBODIMENT

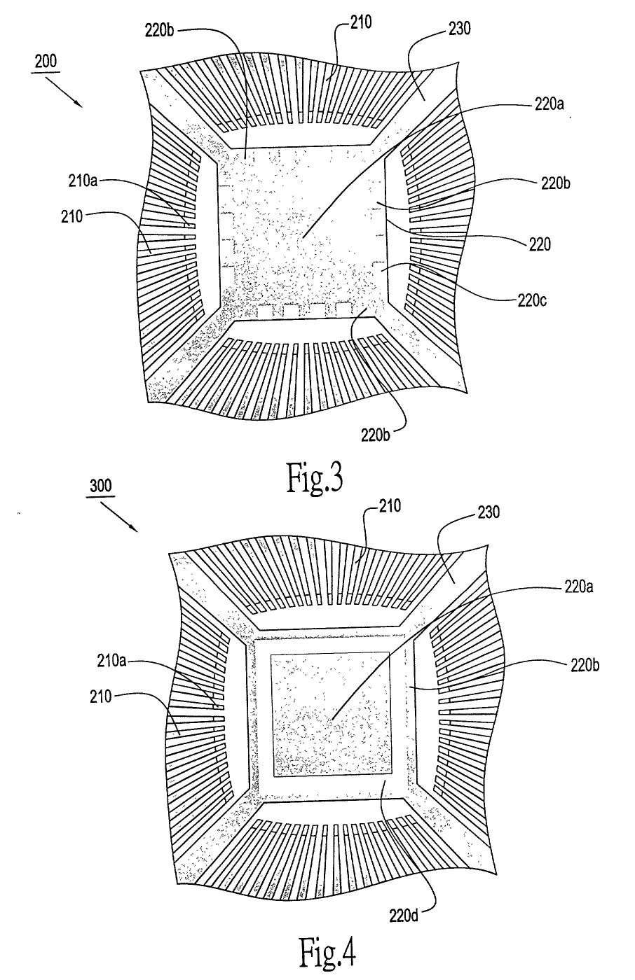

FIG. 3 illustrates a lead frame 200 in accordance with a first preferred embodiment of the present invention. Lead frames may be manufactured in long strips of many individual units (only one shown in FIG. 3). The lead frame 200 includes a plurality of leads 210 arranged around a die pad 220. The die pad 220 is connected to the lead frame by tie bars 230. The lead frame 200 is formed from a thin metal strip, which has been etched or stamped to form a pattern similar to that shown in FIG. 3. Preferably, the lead frame 200 is made of copper or alloys containing copper. Alternatively, the lead frame may be made of iron, nickel or alloys thereof, and then plated with copper. Usually, areas 210a on the leads 210 adapted for wire bonding are plated with at least one noble metal. As shown in FIG. 3, the lead frame 200 is characterized in that the at least one noble metal is plated on one surface of die pad in a manner that a central region 220a for receiving a semiconductor chip as well as at least a portion of the brim region 220b of the die pad 220 are kept un-plated. Preferably, the noble metal is selected from the group consisting of silver, gold, and palladium that bond well with conventional bonding wire material. Specifically, areas 210a on the leads 210 as well as areas 220c on the die pad 220 are plated with Ag, Ni/Pd, or Ni/Pd/Au such that stable gold wire bonding can be achieved.

FIG. 4 illustrates a lead frame 300 in accordance with a second preferred embodiment of the present invention. Lead frame 300 is substantially identical to lead frame 200 of FIG. 3 with exception that the brim region 220b of the die pad 220 is totally kept un-plated such that the noble metal plating region 220d on the die pad 220 is in the shape of a rectangular belt.

FIG. 5 illustrates a lead frame 400 in accordance with a third preferred embodiment of the present invention. Lead frame 400 is substantially identical to lead frame 300 of FIG. 4 with exception that the noble metal plating region 220d on the surface of the die pad 220 is formed in an broken “rectangular belt” pattern.

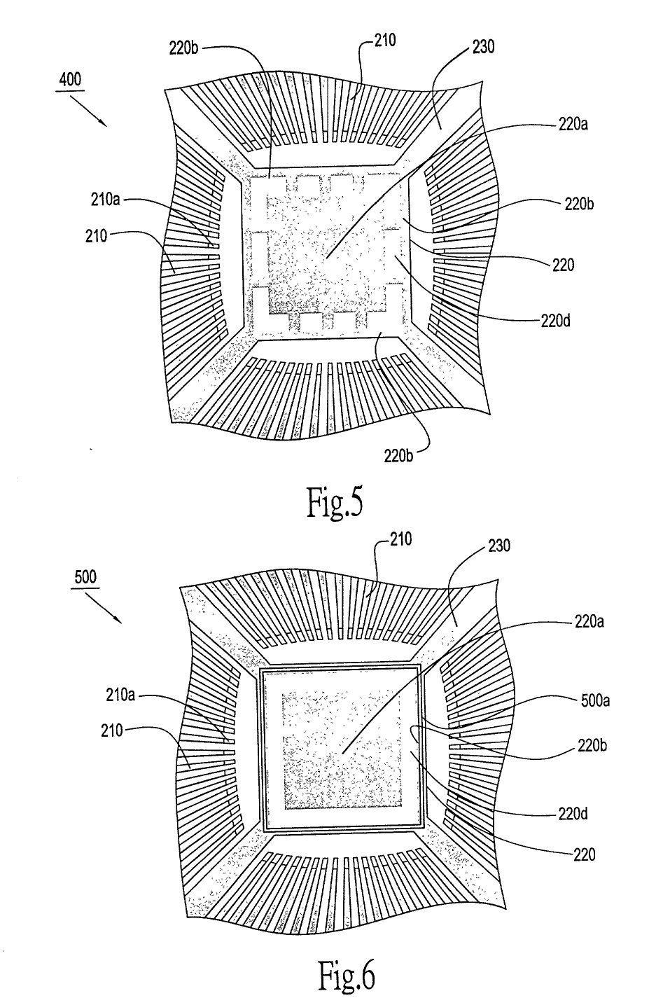

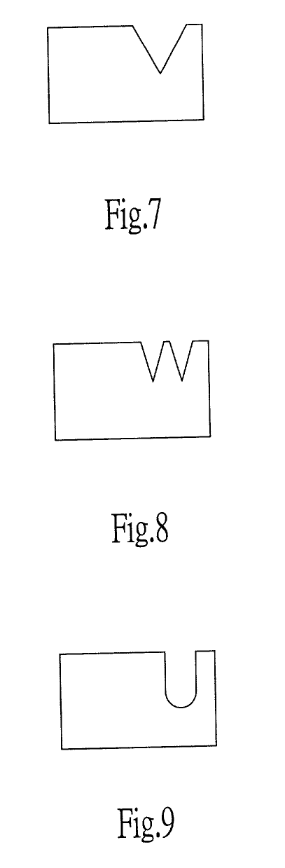

FIG. 6 illustrates a lead frame 500 in accordance with a fourth preferred embodiment of the present invention. Lead frame 500 is substantially identical to lead frame 300 of FIG. 4 with exception that a rectangular groove 500a is formed in the brim region 220b of the die pad 220. Preferably, the groove 500a may has a V-shaped profile (see FIG. 7), a W-shaped profile (see FIG. 8) or a U-shaped profile (see FIG. 9).

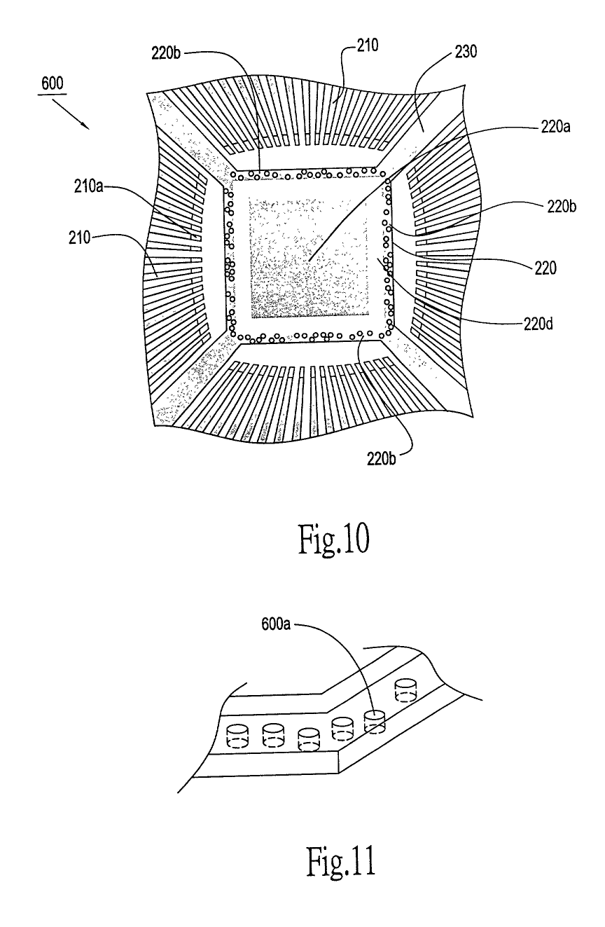

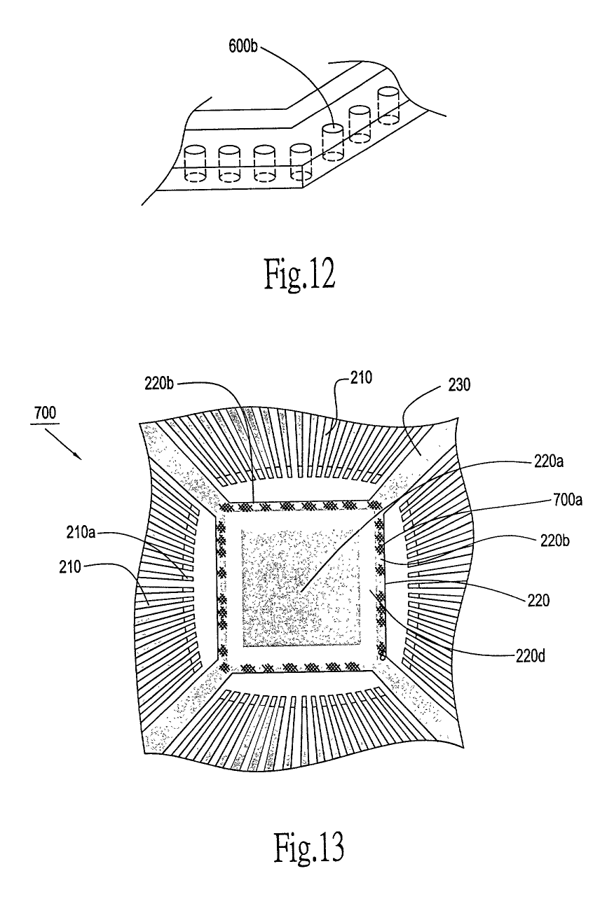

FIG. 10 shows a top plan view of a lead frame 600 in accordance with a fifth preferred embodiment of the present invention. Lead frame 600 is substantially identical to lead frame 300 of FIG. 4 with exception that a plurality of cavities 600a (see FIG. 11) or through-holes 600b (see FIG. 12) are formed in the brim region 220b of the die pad 220.

FIG. 13 shows a top plan view of a lead frame 700 in accordance with a sixth preferred embodiment of the present invention. Lead frame 700 is substantially identical to lead frame 300 of FIG. 4 with exception that a plurality of notches 700a are formed in the brim region 220b of the die pad 220 in a mesh type pattern.

It is noted that the brim region of the die pad in accordance with the present invention preferably has a width less than about 1 mm.

The present invention further provides plastic molded type semiconductor packages using the lead frames described above. In the semiconductor package of the present invention, a semiconductor chip is securely attached onto the central region of the die pad. The semiconductor chip has a plurality of bonding pads coupled to the noble metal plating areas of the leads and the die pad through a plurality of bonding wires. The lead frame, the semiconductor chip and the bonding wires are encapsulated in a package body in a manner that each lead of the lead frame has at least a portion left exposed for electrical connection to outside. Typically, this is accomplished by positioning the lead frame, the semiconductor chip and the bonding wires in a cavity of a molding die, and thereafter, transferring a hardenable molding compound into the cavity.

Since adhesion between molding compound and copper is better than adhesion between molding compound and noble metals described above, bare copper surface on the un-plated region of the die pad provides improved adhesion to molding compound. Furthermore, the rectangular groove, cavities, mesh-type notches, or through-holes formed in the un-plated brim region of the die pad are used to provide mechanical interlock mechanism thereby further reinforcing and stabilizing the bonding between the die pad and the package body. Therefore, the lead frame of the present invention is capable of reducing the occurrence of delamination between molding compound and the brim region of the die pad when the finished package is subjected to pressure cooker test (PCT), temperature cycling, or preconditioning including IR Reflow.

Although the invention has been explained in relation to its preferred embodiment, it is to be understood that many other possible modifications and variations can be made without departing from the spirit and scope of the invention as hereinafter claimed.

What is claimed is:

1. A lead frame for a plastic molded type semiconductor package, the lead frame comprising a plurality of leads and a die pad surrounded by the leads wherein a surface of the die pad is adapted for mounting a semiconductor chip and areas on the leads adapted for wire bonding are plated with at least one noble metal, the lead frame being characterized in that the at least one noble metal is plated on the surface of die pad in a manner that a central region on the surface of the die pad for receiving the semiconductor chip is kept un-plated as well as at least a portion of the brim region of the die pad is kept un-plated.

2. The lead frame as claimed in claim 1, wherein the noble metal plating is for wire bonding purpose and the at least one noble metal is selected from the group consisting of silver, gold, and palladium.

3. The lead frame as claimed in claim 1, wherein the brim region of the die pad is totally kept un-plated.

4. The lead frame as claimed in claim 3, wherein the noble metal plating region on the surface of the die pad is in the shape of a rectangular belt.

5. The lead frame as claimed in claim 4, wherein the noble metal plating region on the surface of the die pad is formed in an broken “rectangular belt” pattern.

6. The lead frame as claimed in claim 3, further comprising a rectangular groove formed in the brim region of the die pad.

7. The lead frame as claimed in claim 6, wherein the groove has a V-shaped profile.

8. The lead frame as claimed in claim 6, wherein the groove has a W-shaped profile.

9. The lead frame as claimed in claim 6, wherein the groove has a U-shaped profile.

10. The lead frame as claimed in claim 3, further comprising a plurality of cavities formed in the brim region of the die pad.

11. The lead frame as claimed in claim 3, further comprising a plurality of notches formed in the brim region of the die pad in a mesh type pattern.

12. The lead frame as claimed in claim 3, further comprising a plurality of through-holes formed in the brim region of the die pad.

13. The lead frame as claimed in claim 3, wherein the brim region of the die pad has a width less than about 1 mm.

14. A plastic molded type semiconductor package comprising:
a lead frame including a plurality of leads and a die pad surrounded by the leads wherein areas on the leads adapted for wire bonding are plated with at least one noble metal, the lead frame being characterized in that the at least one noble metal is plated on the die pad in a manner that a central region as well as at least a portion of the brim region of the die pad is kept un-plated;
a semiconductor chip securely attached onto the central region of the die pad, the semiconductor chip having a plurality of bonding pads;
a plurality of bonding wires for electrical connection between the bonding pads and the noble metal plating areas of the leads and the die pad; and
a package body encapsulating the lead frame, the semiconductor chip and the bonding wires wherein each lead of the lead frame has at least a portion left exposed for electrical connection to outside.

15. The semiconductor chip package as claimed in claim 14, wherein the at least one noble metal is selected from the group consisting of silver, gold, and palladium.

16. The semiconductor chip package as claimed in claim 14, wherein the brim region of the die pad is totally kept un-plated.

17. The semiconductor chip package as claimed in claim 16, wherein the noble metal plating region on the surface of the die pad is in the shape of a rectangular belt.

18. The semiconductor chip package as claimed in claim 17, wherein the noble metal plating region on the surface of the die pad is formed in an broken “rectangular belt” pattern.

19. The semiconductor chip package as claimed in claim 16, further comprising a rectangular groove formed in the brim region of the die pad.

20. The semiconductor chip package as claimed in claim 19, wherein the groove has a V-shaped profile.

21. The semiconductor chip package as claimed in claim 19, wherein the groove has a W-shaped profile.

22. The semiconductor chip package as claimed in claim 19, wherein the groove has a U-shaped profile.

23. The semiconductor chip package as claimed in claim 16, further comprising a plurality of cavities formed in the brim region of the die pad.

24. The semiconductor chip package as claimed in claim 16, further comprising a plurality of notches formed in the brim region of the die pad in a mesh type pattern.

25. The semiconductor chip package as claimed in claim 16, further comprising a plurality of through-holes formed in the brim region of the die pad.

26. The semiconductor chip package as claimed in claim 16, wherein the brim region of the die pad has a width less than about 1 mm.
